(19) United States
(12) Patent Application Publication
(10) Pub. No.: US 2026/0293243 A1
(43) Pub. Date: Sep. 24, 2026

(54) SEMICONDUCTOR DEVICE

(71) Applicant: Vanguard International Semiconductor Corporation, Hsinchu (TW)

(72) Inventors: Shyh-Chiang SHEN, Hsinchu City (TW); Wei-Chih CHENG, Tainan City (TW); Po-Heng LIN, New Taipei City (TW)

(73) Assignee: Vanguard International Semiconductor Corporation, Hsinchu (TW)

(21) Appl. No.: 19/085,633

(22) Filed: Mar. 20, 2025

(51) Int. Cl. H10D 62/10; H10D 8/00; H10D 8/60; H10D 30/47; H10D 62/60; H10D 62/824; H10D 64/64; H10D 84/00

(52) U.S. Cl. CPC H10D 62/124; H10D 8/411; H10D 8/60; H10D 30/472; H10D 30/475; H10D 62/60; H10D 62/824; H10D 64/64; H10D 84/101

(57) ABSTRACT

A semiconductor device is provided. The semiconductor device includes a substrate, a buffer layer, a channel layer, a barrier layer, a gate structure, a first N-type cap layer and a gate electrode layer. The buffer layer is located on the substrate. The channel layer is located on the buffer layer. The barrier layer is located on the channel layer. The gate structure is located on the barrier layer. The first N-type cap layer is located on the channel layer. The first N-type cap layer is lightly doped. The gate electrode layer is located on the first N-type cap layer.

### BACKGROUND OF THE INVENTION

### Field of the Invention

The present disclosure relates to a semiconductor device, and, in particular, it relates to a high electron mobility transistor device.

### Description of the Related Art

Gallium nitride-based (GaN-based) semiconductor materials have many excellent material properties, such as high thermal resistance, wide band-gap, high electron saturation rate, and good heat dissipation. GaN-based semiconductor materials are suitable for operation in high-frequency and high-temperature environments. In recent years, gallium nitride semiconductor materials have been used in fast-charging equipment, power supply modules of wireless communication base stations, components of electric vehicle, and other high electron mobility transistor (HEMTs) devices having heterogeneous interface structures.

High electron mobility transistors are also called heterostructure field effect transistors (HFET) and modulation-doped field effect transistors (MODFET), which include semiconductor materials that have different energy gaps to produce a two-dimensional electron gas (2DEG) layer at the interface between different semiconductor materials that are adjacent. High electron mobility transistors may be affected by fabrication processes, resulting in poor electrical performance or uniformity. Therefore, a novel structure that can further improve the performance and reliability of high electron mobility transistor devices is still one of the current research topics in the industry.

### BRIEF SUMMARY OF THE INVENTION

An embodiment of the disclosure provides a semiconductor device. The semiconductor device includes a substrate, a buffer layer, a channel layer, a barrier layer, a gate structure, a first N-type capping layer and a gate electrode layer. The buffer layer is located on the substrate. The channel layer is located on the buffer layer. The barrier layer is located on the channel layer. The gate structure is located on the barrier layer. The first N-type capping layer is located on the channel layer. The first N-type capping layer is lightly doped. The gate electrode layer is located on the first N-type capping layer.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device in accordance with some embodiments of the disclosure;

FIG. 2 is a schematic cross-sectional view of a semiconductor device in accordance with some embodiments of the disclosure;

FIG. 3 is a schematic cross-sectional view of a semiconductor device in accordance with some embodiments of the disclosure;

FIG. 4 is a schematic cross-sectional view of a semiconductor device in accordance with some embodiments of the disclosure;

FIG. 5 is a schematic cross-sectional view of a semiconductor device in accordance with some embodiments of the disclosure; and

FIG. 6 is the electric field distribution of a gate electrode layer, a first N-type capping layer and a gate structure of the semiconductor device in FIG. 1.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

In the conventional enhancement-mode high electron mobility transistors (E-mode GaN HEMT), the P-type gate enhancement-mode high electron mobility transistor has been widely used due to the advantages combining good electrical properties, reliability and process compatibility. However, during the operation of the P-type gate E-mode GaN HEMT, the gate voltage swing performance will be affected due to interface defects of the P-type gate. Therefore, a novel enhancement-mode high electron mobility transistor is desired to solve or improve the abovementioned problems.

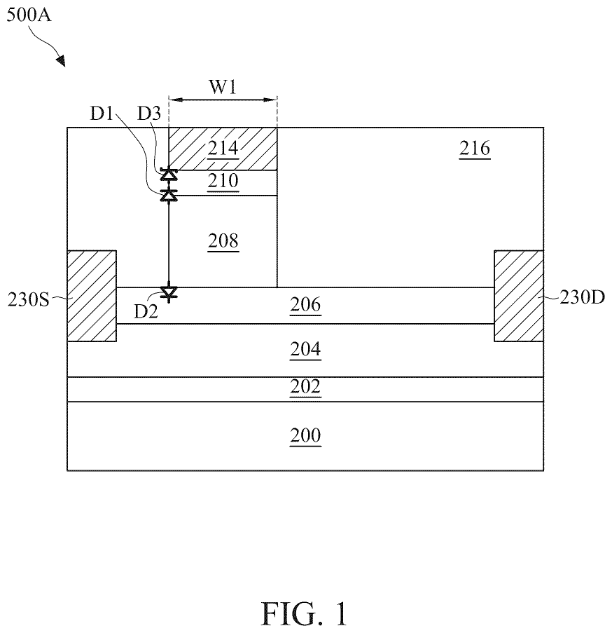

FIG. 1 is a schematic cross-sectional view of a semiconductor device 500A in accordance with some embodiments of the disclosure. In some embodiments, the semiconductor device 500A includes a high electron mobility transistor (HEMT), such as a gallium nitride-based enhancement-mode high electron mobility transistor (E-mode GaN HEMT). As shown in FIG. 1, the semiconductor device 500A includes a substrate 200, a buffer layer 202, a channel layer 204, a barrier layer 206 and a gate structure 208.

In some embodiments, the substrate 200 includes an elementary semiconductor including silicon (Si) or germanium (Ge); a compound semiconductor including gallium arsenide (GaAs), gallium phosphide (GaP), indium phosphide (InP), indium arsenide (InAs) and/or indium antimonide (InSb); an alloy semiconductor including SiGe, GaAsP, AlInAs, AlGaAs, GaInAs, GaInP, and/or GaInAsP, or a combination thereof.

In some embodiments, the substrate 200 may be a semiconductor on insulator substrate, such as a silicon on insulator (SOI) substrate or a silicon germanium on insulator (SGOI) substrate. In other embodiments, the substrate 200 may be a ceramic substrate, such as an aluminum nitride (AlN) substrate, a silicon carbide (SiC) substrate, an aluminum oxide (Al₂O₃) substrate (or called a sapphire substrate), a glass substrate, or other similar substrates. In some embodiments, the substrate 200 may include a ceramic substrate and a pair of blocking layers respectively disposed on upper and lower surfaces of the ceramic substrate. The ceramic substrate may include a ceramic material, and the ceramic material may include a metal-inorganic material. For example, the ceramic substrate may include silicon carbide (SiC), aluminum nitride (AlN), sapphire substrate, or other suitable materials. The sapphire substrate may be aluminum oxide. In some embodiments, the blocking layers located on the top and bottom surfaces of the ceramic substrate may include a single layer or multiple layers of insulating material and/or other suitable material layers, such as semiconductor layers. The insulating material layer may be oxide, nitride, oxynitride, or other suitable insulating materials. The semiconductor layer may be polysilicon. The blocking layer may be capable of preventing the diffusion of the ceramic substrate. The blocking layer may also prevent the ceramic substrate from interacting with other film layers or processing tools. In some embodiments, the blocking layer may also encapsulate the ceramic substrate. At this time, the barrier layer may not only cover the top and bottom surfaces of the ceramic substrate, but also cover both side surfaces of the ceramic substrate.

As shown in FIG. 1, the buffer layer 202 is located on the top surface 200T of the substrate 200. Since the crystal lattice and the coefficient of thermal expansion of the substrate 200 may be different from those of the features (such as a channel layer 204) above the substrate 200, strains may occur at or near the interface between the substrate 200 and the features above the substrate 200, resulting in defects such as cracks or warpage. Therefore, the buffer layer 202 on the substrate 200 can relief the strains in the features formed above the buffer layer 202 (e.g., the channel layer 204), preventing defects from forming in the above features. In some embodiments, the material of the buffer layer 202 may include III-V compound semiconductor materials, such as III-nitride. For example, the material of the buffer layer 202 may include: aluminum nitride (AlN), gallium nitride (GaN), aluminum gallium nitride (AlₓGa₁₋ₓN, where 0<x<1), aluminum nitride Indium (AlInN), a combination of thereof, or other similar materials. In some embodiments, the buffer layer 202 may be formed by an epitaxial growth process, such as metal organic chemical vapor deposition (MOCVD), organic metal vapor epitaxy (OMVPE)), molecular beam epitaxy (MBE), hydride vapor phase epitaxy (HVPE), plasma-assisted chemical vapor deposition (PECVD), atomic layer deposition (ALD), other suitable methods, or a combination thereof. In some embodiments, the buffer layer 202 may be a multi-layer structure (not shown). For example, the buffer layer 202 may include a superlattice buffer layer and/or a gradient buffer layer. The superlattice buffer layer may be disposed on the substrate 200, and the gradient buffer layer is disposed on the superlattice buffer layer. The buffer layer 202 may effectively prevent dislocations in the substrate 200 from entering the features above the substrate 200. The buffer layer 202 may further improve the crystallization quality of other overlying films and/or layers.

In some embodiments, the semiconductor device 500A may optionally include a seed layer (not shown) between the substrate 200 and the buffer layer 202. The seed layer can relieve the lattice difference between the substrate 200 and the films and/or layers growing thereon, so as to improve the crystallization quality. In some embodiments, the material of the seed layer may include aluminum nitride (AlN), aluminum gallium nitride (AlGaN), other suitable materials, or a combination of thereof. In some embodiments, the seed layer of a single-layer or multi-layer structure may be formed by, for example, chemical vapor deposition (CVD), atomic layer deposition (ALD), physical vapor deposition (PVD), other suitable processes, or a combination of thereof.

The channel layer 204 is located on the buffer layer 202. In some embodiments, the material of the channel layer 204 includes a binary compound semiconductor of group III-V, such as group-III nitride. For example, the material of the channel layer 204 includes gallium nitride (GaN). In some embodiments, the channel layer 204 may be doped with n-type dopants or p-type dopants. In some embodiments, the channel layer 204 may be formed by an epitaxial growth process, such as metal organic chemical vapor deposition (MOCVD), organic metal vapor epitaxy (OMVPE), molecular beam epitaxy (MBE), hydride vapor epitaxy (HVPE), plasma-assisted chemical vapor deposition (PECVD), atomic layer deposition (ALD), ammonothermal growth, other suitable processes, or a combination thereof. It should be noted that in some embodiments, the term “undoped feature” refers to a feature that has not been doped using a diffusion or ion implantation process. However, during subsequent processes, dopants may inadvertently diffuse into the feature, leaving it with a low or negligible doping concentration.

In some embodiments in which a GaN layer is as the channel layer, the breakdown voltage of the high electron mobility transistor may be improved by increasing the thickness of the GaN layer. However, for applications with high operating voltages, such as above 3V, the increasement of the thickness of the GaN layer has limited effect on the breakdown voltage of high electron mobility transistors. In such an embodiment, in order to form a thicker GaN layer material on the substrate, it is necessary to use a substrate with high thermal conductivity and high mechanical strength. Otherwise, the problems of substrate bending or even substrate cracking may occur. It should be noted that the aforementioned materials are only examples and do not limit the present invention.

The barrier layer 206 is located on the channel layer 204. The material of the barrier layer 206 may include a ternary compound semiconductor of group III-V, such as group-III nitride. For example, the material of the barrier layer 206 may be aluminum gallium nitride (AlGaN), aluminum indium nitride (AlInN), or a combination thereof. In other embodiments, the barrier layer 206 may also include gallium nitride (GaN), aluminum nitride (AlN), gallium arsenide (GaAs), indium gallium phosphide (InGaP), aluminum gallium arsenide (AlGaAs)), indium phosphide (InP), aluminum indium arsenide (InAlAs), indium gallium arsenide (InGaAs), indium gallium arsenide phosphide (InGaAsP), gallium arsenic antimonide (GaAs Sb), other suitable III-V materials, or a combination thereof. In some embodiments, the barrier layer 206 may be doped with N-type dopants or P-type dopants. In some embodiments, the barrier layer 206 may be undoped. In this embodiment, the barrier layer 206 has N-type dopants. In some embodiments, the barrier layer 206 may be formed by an epitaxial growth process, such as metal organic chemical vapor deposition (MOCVD), organic metal vapor epitaxy (OMVPE), molecular beam epitaxy (MBE), hydride vapor epitaxy (HVPE), plasma-assisted chemical vapor deposition (PECVD), atomic layer deposition (ALD), ammonothermal growth, other suitable processes, or a combination thereof.

According to some embodiments of the disclosure, the channel layer 204 and the barrier layer 206 include different materials, and the interface between the channel layer 204 and the barrier layer 206 is a heterojunction structure. The heterojunction formed between the channel layer 204/barrier layer 206 is, for example, AlGaAs/GaAs heterojunction, InGaP/GaAs heterojunction, InGaAs/InP heterojunction, InGaAsP/InP heterojunction, GaAsSb/InP heterojunction or SiGe/Si heterojunction. The lattice mismatch between the channel layer 204 and barrier layer 206 may result in stress that leads to piezoelectric polarization effect. In addition, the ionicity of the bonding between the group-III metals (such as aluminum (Al), gallium (Ga), or indium (In)) and nitrogen bonding is relatively strong, thereby resulting in spontaneous polarization. Due to the difference in energy gap between the heterogeneous materials of the channel layer 204 and the barrier layer 206 and the aforementioned piezoelectric polarization and spontaneous polarization effects, two-dimensional electron gas (2DEG) (not shown) is formed at the heterogeneous interface between the channel layer 204 and the barrier layer 206. In some embodiments, the two-dimensional electron gas is used as the conductive carriers of the semiconductor device 500A.

The gate structure 208 is disposed on the barrier layer 206 and covers a portion of the barrier layer 206. In this embodiment, the gate structure 208 includes a P-type GaN layer. Moreover, the gate structure 208 has a uniform width W1.

The gate structure 208 is located on a portion of the barrier layer 206 and is in contact with the barrier layer 206. In some embodiments, the gate structure 208 may also serve as a gate layer. As shown in FIG. 1, the gate structure 208 may have a rectangular cross-section as shown in FIG. 1. In other embodiments, the cross section of the gate structure 208 may also be in other shapes, such as a trapezoidal cross section. In some embodiments, the gate layer 208 is formed by metal organic chemical vapor deposition (MOCVD), organometallic vapor epitaxy (OMVPE), molecular beam epitaxy (MBE), hydride vapor epitaxy (HVPE), plasma-assisted chemical vapor deposition (PECVD), atomic layer deposition (ALD), ammonothermal growth, a combination of thereof, or other suitable methods and subsequent patterning process. The gate layer 208 may be doped. In some embodiments, the dopants of the gate structure 208 may include magnesium (Mg), carbon (C), fluorine (F), boron (B), zinc (Zn), calcium (Ca), beryllium (Be), strontium (Sr), barium (Ba), radium (Ra), silver (Ag), gold (Au), lithium (Li) or sodium (Na). In some embodiments, the gate structure 208 has a doping concentration of about 1E15 cm⁻³ to 1E20 cm⁻³, for example, about 1E17 cm⁻³ to 4E19 cm⁻³. In some embodiments, the gate structure 208 has a thickness of about 2 nm to 300 nm, such as about 10 nm to 300 nm.

A first N-type capping layer 210 of the semiconductor device 500A is located on the gate structure 208. The first N-type capping layer 210 is in contact with and fully covers the gate structure 208. In some embodiments, the first N-type capping layer includes In₁₋ₓAlₓN or AlₓGa₁₋ₓN, where x representing the content of aluminum in the first N-type capping layer 210 may be a variable, and x ranges greater than 0 and less than 1, that is, 0<x<1. In another embodiment, the first N-type capping layer includes Al_{xI}n_{y}Ga_{1-x-y)}, where x and y may be variables greater than 0 and less than 1 respectively.

As shown in FIG. 1, the first N-type capping layer 210 may have a rectangular cross-section as shown in FIG. 1. In other embodiments, the cross section of the first N-type capping layer 210 may also be in other shapes, such as a trapezoidal cross section. The gate structure 208 and the first N-type capping layer 210 may have a uniform width W1.

In some embodiments, the energy gap of the first N-type capping layer 210 is greater than the energy gap of the gate structure 208. For example, the difference between the energy gap of the first N-type capping layer 210 and the energy gap of the gate structure 208 is greater than or equal to about 25 meV. If the difference between the energy gap of the first N-type capping layer 210 and the energy gap of the gate structure 208 is less than about 25 meV, the energy gap difference between the first N-type capping layer 210 and the gate structure 208 is not enough to affect the electrical properties of the material at room temperature.

In some embodiments, the dopant of the first N-type capping layer 210 may include silicon, germanium, sulfur, phosphorus or a combination thereof. In some embodiments, the first N-type capping layer 210 is a lightly doped N-type AlₓGa₍₁₋ₓ₎N layer. In a preferred example, the light doping concentration is about 1E16 cm⁻³ to 1E18 cm⁻³. In one embodiment, if the doping concentration of the first N-type capping layer 210 exceeds about 1E18 cm⁻³, for example, about 1E19 cm⁻³, the breakdown voltage of the gate structure 208 will be reduced. If the doping concentration is lower than about 1E15 cm⁻³, the surface electric field of the gate structure 208 will be higher and more surface defects will be formed on the gate structure 208, which is disadvantaged to the electrical performance of the device. In some embodiments, the thickness of the first N-type capping layer 210 is about 1 nm to 1000 nm, for example, about 1 nm to 300 nm.

The semiconductor device 500A also includes a gate electrode layer 214. The gate electrode layer 214 is located on the first N-type capping layer 210 and fully covers the first N-type capping layer 210. In this embodiment, the gate electrode layer 214 and the first N-type capping layer 210 have the same width W1. In some embodiments, the gate electrode layer 214 may include a single-layer or multi-layer structure, or a combination thereof formed by materials including metal, metal nitride, metal oxide, metal alloy, other suitable conductive materials, or a combination thereof. The metals may include, for example, gold (Au), nickel (Ni), platinum (Pt), palladium (Pd), iridium (Ir), titanium (Ti), chromium (Cr), tungsten (W), aluminum (Al), copper (Cu), similar materials, an alloy thereof, or a combination thereof. The metal alloy may include titanium tungsten (TiW). The metal nitrides may include molybdenum nitride (MoN), tungsten nitride (WN), titanium nitride (TiN), tantalum nitride (TaN), tantalum silicon nitride (TaSiN), tantalum carbide nitride (TaCN), nitrogen aluminum titanium (TiAlN), or other similar materials. In other embodiments, the conductive material of the gate electrode layer 218G may include nickel silicide (NiSi), cobalt silicide (CoSi), tantalum carbide (TaC), titanium aluminide (TiAl), or other similar materials. For example, the gate electrode layer 214 has a Ti/Al/Ti/Au metal stack structure. In this embodiment, the gate electrode layer 214 is in contact with the first N-type capping layer 210 to form a Schottky contact.

As shown in FIG. 1, the semiconductor device 500A further includes a source electrode 230S and a drain electrode 230D. The source electrode 230S and the drain electrode 230D are respectively disposed on the channel layer 204 and located on opposite sides of the gate structure 208 and the first N-type capping layer 210. The source electrode 230S and the drain electrode 230D respectively penetrate the barrier layer 206 to be in contact the channel layer 204. In some embodiments, the source electrode 230S and the drain electrode 230D further extend into a portion of the channel layer 204.

In some embodiments, the semiconductor device 500A further includes a protective layer 216 disposed on the barrier layer 206, the gate structure 208, the first N-type capping layer 210, the source electrode 230S and the drain electrode 230D. The material of the protective layer 216 may include silicon oxide (SiO2), silicon oxynitride (SiON), aluminum oxide (Al₂O₃), aluminum nitride (AlN), polyimide (PI), benzocyclobutene (BCB), polybenzoxazole (PBO), other insulating materials, or a combination thereof. In some embodiments, the protective layer 216 may be formed using organic metal vapor deposition, chemical vapor deposition, spin coating, other suitable methods, or a combination thereof.

In some embodiments, the material of the source electrode 230S and the drain electrode 230D may include a single-layer or multi-layer structure formed of a conductive material such as a metal material. For example, it may include a single-layer or multi-layer structure formed by metal, metal nitride, metal oxide, metal alloy, other suitable conductive materials, or a combination of thereof, or a combination of thereof. For example, the metal may include gold (Au), nickel (Ni), platinum (Pt), palladium (Pd), iridium (Ir), titanium (Ti), chromium (Cr), tungsten (W), aluminum (Al), copper (Cu), similar materials, an alloy thereof, or a combination thereof. The metal alloys may include titanium tungsten (TiW). Metal nitrides may include: molybdenum nitride (MoN), tungsten nitride (WN), titanium nitride (TiN), tantalum nitride (TaN), tantalum silicon nitride (TaSiN), tantalum carbide nitride (TaCN), nitrogen Titanium aluminum oxide (TiAlN), or other similar materials. In other embodiments, the conductive material of the source electrode 230S and the drain electrode 230D may include nickel silicide (NiSi), cobalt silicide (CoSi), tantalum carbide (TaC), titanium aluminide (TiAl), or other similar materials. For example, the source electrode 230S and the drain electrode 230D have a Ti/Al/Ti/Au metal stack structure.

A method of forming the semiconductor device 500A will be described in the following. First, a substrate 200 is provided. Then, several epitaxial growth processes are performed to sequentially form a buffer layer 202, a channel layer 204, a barrier layer 206, a gate material layer (not shown) and a first N-type capping layer material (not shown) on the top surface of the substrate 200. In some embodiments, the above-described layers may be in-situ deposited in the same deposition chamber. Next, a patterning process is performed to remove a portion of the gate material layer and a portion of the first N-type capping layer material to form a multi-layer stack including a gate structure 208 and a first N-type capping layer 210 (or multi-layer mesa). In some embodiments, the patterning process includes a photolithography process and a subsequent etching process. Then, several deposition processes and patterning processes are performed to form a gate electrode layer 214 on the first N-type capping layer 210, and to form a source electrode 230S and a drain electrode 230D on the opposite sides of the gate structure 208 and the first N-type capping layer 210. The source electrode 230S and the drain electrode 230D passes through the barrier layer 206 and are in contact with the channel layer 204. In some embodiments, both the source electrode 230S and the drain electrode 230D form ohmic contacts with the channel layer 204. Next, a deposition or coating process is performed to form a protective layer 216 on the barrier layer 206, the gate structure 208, the source electrode 230S and the drain electrode 230D. After performing the above processes, a semiconductor device 500A in accordance with some embodiments of the disclosure is formed.

In the semiconductor device 500A, the equivalent circuit of the gate electrode layer 214, the first N-type capping layer 210, the gate structure 208 and the barrier layer 206 and the undoped channel layer 204 under the gate structure 208 may serve as a diode D1, a diode D2 and a Schottky diode D3 connected in series. The diode D1 is formed by the first N-type capping layer 210 and the gate structure 208. The diode D2 is formed by the gate structure 208, the barrier layer 206, and the channel layer 204 (p-GaN/AlGaN/GaN). The Schottky diode D3 is formed by the first N-type capping layer 210 and the gate electrode layer 214. As shown in FIG. 1, the diode D1 and the diode D2 are connected back-to-back. In addition, the anode of the diode D1 is coupled to the cathode of the Schottky diode D3.

In the case that the gate (the gate structure 208) is reverse biased, the diode D1 and the Schottky diode D3 are forward biased, and the diode D2 is reverse biased. In this case, the leakage current is dominated by the reverse-biased diode D2 (p-GaN/AlGaN/GaN). In the case that the gate (the gate structure 208) is forward biased, the diode D1 and the Schottky diode D3 are reverse biased, and the diode D2 is forward biased. Compared with the Schottky diode D3, the depletion region of the diode D1 extends to the N and P sides. Furthermore, since the first N-type capping layer 210 of the diode D1 is lightly doped, the diode D1 may have a larger width of the depletion region. Therefore, under the same peak electric field, the diode D1 may withstand a higher voltage, reduce holes injected from the gate electrode layer 214, and exhibit lower leakage current. Therefore, the leakage current and the breakdown voltage of the gate mainly are dominated by the reverse biased diode D1.

In addition, in the case that the gate (the gate structure 208) is forward biased, the electric field peak is located in the PN junction of the diode D1 instead of the Schottky junction between the gate electrode layer 214 and the first N-type capping layer 210. Therefore, the electrical performance of the semiconductor device is not affected by the interface conditions (such as defects) between the first N-type capping layer 210 and the gate electrode layer 214. The electric field at the interface between the first N-type capping layer 210 and the gate electrode layer 214 can be reduced. In addition, the gate breakdown voltage can be effectively increased.

In some embodiments, since the energy gap of the first N-type capping layer 210 is larger than the gate structure 208, hole injection can be effectively suppressed, the reliability of the gate layer (the gate structure 208) can be improved. In addition, the maximum gate voltage swing can be improved.

In some embodiments, the composition of aluminum in the first N-type capping layer 210 can further reduce the interface electric field between the gate electrode layer 214 and the first N-type capping layer 210.

On the other hand, the equivalent circuit of the first N-type capping layer 210, the gate structure 208 and the barrier layer 206 and the undoped channel layer 204 under the gate structure 208 may be regarded as an open-base NPN bipolar-gate. Therefore, the first N-type capping layer 210, the gate structure 208 and the two-dimensional electron gas channel (2DEG channel) formed by the undoped channel layer 204 and the barrier layer 206 may form an NPN heterojunction bipolar transistor (HBT), may also serve as a bipolar-gate high-electron-mobility transistor (BG-HEMT). Since the NPN HBT has an open-base circuit configuration, the semiconductor device 500A may have a smaller leakage current.

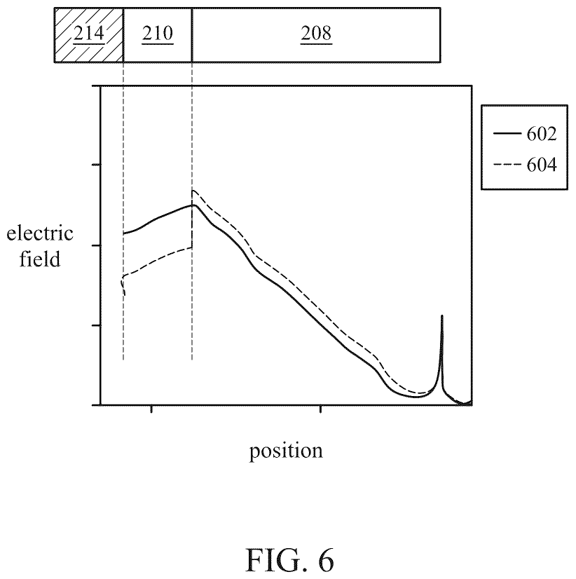

In some embodiments, the collector-emitter breakdown voltage with base open (BV_{CEO}) of the NPN HBT having an open-base circuit configuration determines the maximum gate voltage swing. Furthermore, the doping concentration and the content of aluminum in the first N-type capping layer 210 will affect the collector-emitter breakdown voltage. In some embodiments, since the first N-type capping layer 210 is lightly doped, the collector-emitter breakdown voltage can be significantly increased. Moreover, in some embodiments, in order to both reduce the surface electric field of the gate structure 208 and increase the maximum gate voltage swing, The range of the x value representing the content of aluminum in the first N-type capping layer 210 formed of, including InₓAl₁₋ₓN, AlₓGa₁₋ₓN or AlₓIn_{y}Ga_{1-x-y}N is greater than 0 and less than (or equal to) 0.3, that is, 0<x≤0.3. FIG. 6 illustrates the surface electric field distribution of the gate electrode layer 214, the first N-type capping layer 210 and the gate structure 208 of the semiconductor device 500A. The curves 602 and 604 respectively show the surface electric field distribution with x values equal to 0 and 0.1. It can be seen from the curves 602 and 604 that if the x value is equal to 0, the first N-type capping layer 210 has no content of aluminum and cannot reduce the surface electric field at the interface between the first N-type capping layer 210 and the gate electrode layer 214. If the x value is greater than 0.3, the collector-emitter breakdown voltage will be decreased.

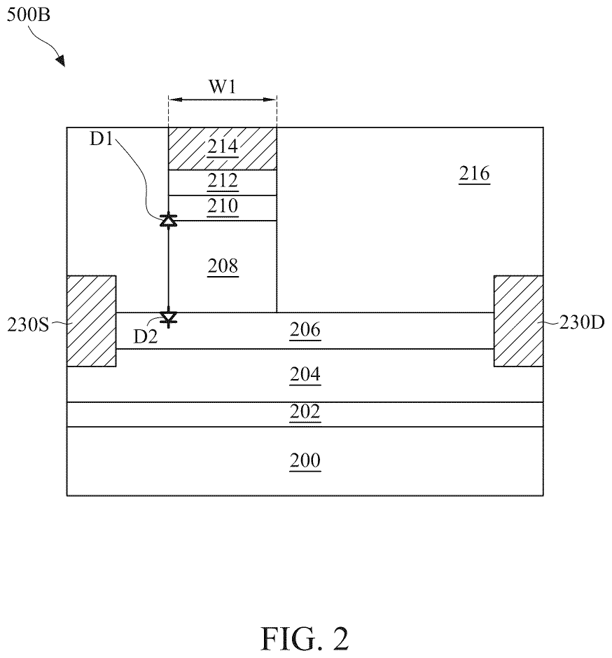

FIG. 2 is a schematic cross-sectional view of a semiconductor device 500B in accordance with some embodiments of the disclosure, in which the reference numbers the same or similar to those in FIG. 1 denote the same or similar elements. As shown in FIG. 2, at least one of the difference between the semiconductor device 500B and the semiconductor device 500A is that the semiconductor device 500B further includes a second N-type capping layer 212 located between the first N-type capping layer 210 and the gate electrode layer 214.

As shown in FIG. 2, the second N-type capping layer 212 is sandwiched between the first N-type capping layer 210 and the gate electrode layer 214. The top surface and the bottom surface of the second N-type capping layer 212 are in contact with the gate electrode layer 214 and the first N-type capping layer 210 respectively.

In this embodiment, the first N-type capping layer 210 and the second N-type capping layer 212 may collectively serve as a capping layer. The first N-type capping layer 210 may be a lightly doped InₓAl₁₋ₓN layer, a lightly doped AlₓGa₁₋ₓN layer, or a lightly doped AlₓIn_{y}Ga_{1-x-y}N layer. In addition, the doping concentration of the lightly doped first N-type capping layer 210 may be about 1E15 cm⁻³ to 1E19 cm⁻³. In a preferred embodiment, the doping concentration is about 1E16 cm⁻³ to 1E18 cm⁻³. If the doping concentration of the first N-type capping layer 210 exceeds about 1E18 cm⁻³, for example, about 1E19 cm⁻³, the breakdown voltage of the gate structure 208 will be reduced. If the doping concentration is lower than about 1E15 cm⁻³, the surface electric field between the second N-type capping layer 212 and the gate electrode layer 214 will be increased. In addition, the interface between the second N-type capping layer 212 and the gate electrode layer 214 may form more surface defects, which is disadvantaged to the electrical performance of the semiconductor device.

As shown in FIG. 2, the second N-type capping layer 212 may have a rectangular cross-section as shown in FIG. 2. In other embodiments, the cross section of the second N-type capping layer 212 may also be in other shapes, such as a trapezoidal cross section. In this embodiment, the gate structure 208, the first N-type capping layer 210 and the second N-type capping layer 212 have a uniform width W1.

In some embodiments, the dopant of the second N-type capping layer 212 may include silicon, germanium, sulfur, phosphorus or a combination thereof. In some embodiments, the second N-type capping layer 212 is a heavily doped N-type InₓAl₁₋ₓN layer, a heavily doped AlₓGa₁₋ₓN layer, or a heavily doped AlₓIn_{y}Ga_{1-x-y}N layer, where x and y may be variables greater than 0 and less than 1 respectively. The doping concentration of the second N-type capping layer 212 is greater than the doping concentration of the first N-type capping layer 210. In some embodiments, the doping concentration of the heavily doped second N-type capping layer 212 is about 1E19 cm⁻³ to 1E20 cm⁻³. Therefore, the second N-type capping layer 212 and the gate electrode layer 214 that are in contact with each other may form an ohmic contact. In some embodiments, the thickness of the second N-type capping layer 212 is about 1 nm to 1000 nm, for example, about 1 nm to 300 nm.

At least one of the differences between the formation methods for forming the semiconductor device 500B and the semiconductor device 500A is that, an epitaxial process is performed to form a second capping layer material (not shown) on the first capping material after forming the first N-type capping material (not shown). Next, a patterning process is performed to remove a portion of the P-type GaN material layer, a portion of the first N-type AlₓGa₍₁₋ₓ₎N material layer and the second N-type AlₓGa₍₁₋ₓ₎N material layer, so as to form a multi-layer stack (or multi-layer mesa) including the gate structure 208, the first N-type capping layer 210 and the second N-type capping layer 212 is formed. Next, the intermediate processes similar to those of the semiconductor device 500A are performed to form the gate electrode layer 214, the source electrode 230S, the drain electrode 230D and the protective layer 216. After the above process, the semiconductor device 500B in accordance with some embodiments of the disclosure is formed.

In the semiconductor device 500B, the gate electrode layer 214 and the second N-type capping layer 212 form an ohmic contact. In this embodiment, the equivalent circuit of the second N-type capping layer 212, the first N-type capping layer 210, the gate electrode layer 214, the first N-type capping layer 210, the gate structure 208 and the barrier layer 206 and the undoped channel layer 204 under the gate structure 208 may serve as a diode D1 and a diode D2 connected back-to-back in series. The equivalent circuit of the second N-type capping layer 212, the first N-type capping layer 210, the gate structure 208 and the barrier layer 206 and the undoped channel layer 204 under the gate structure 208 may be regarded as an open-base NPN bipolar-gate. Therefore, the first N-type capping layer 210, the second N-type capping layer 212, the gate structure 208 and the two-dimensional electron gas channel (2DEG channel) formed by the undoped channel layer 204 and the barrier layer 206 may form an NPN heterojunction bipolar transistor (HBT), may also serve as a bipolar-gate high-electron-mobility transistor (BG-HEMT). Since the NPN HBT has an open-base circuit configuration, the semiconductor device 500B may have a smaller leakage current.

In addition to the advantages of the semiconductor device 500A, the semiconductor device 500B may further reduce the surface electric field at the interface between the gate electrode layer 214 and the second N-type capping layer 212.

In some embodiments, the gate structure of the semiconductor device may have different cross-sectional shapes, such as a ledged shaped cross section (a ledged gate structure).

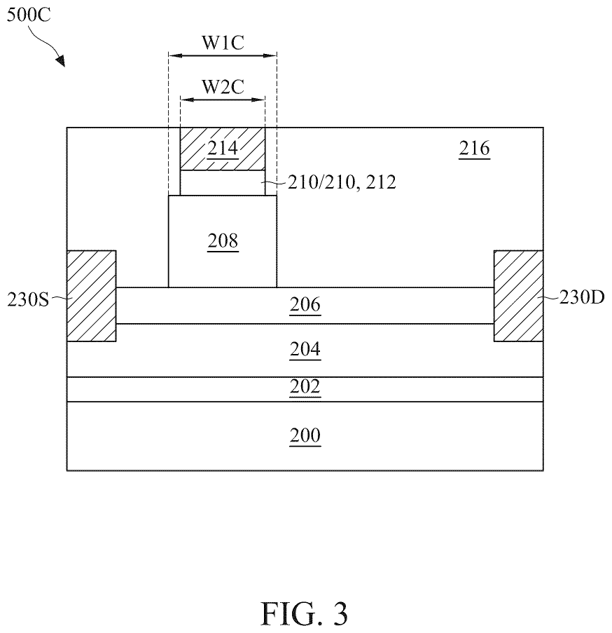

FIG. 3 is a schematic cross-sectional view of a semiconductor device 500C in accordance with some embodiments of the disclosure, in which the reference numbers the same or similar to those in FIGS. 1 and 2 denote the same or similar elements. At least one of the differences between the semiconductor device 500C and the semiconductor devices 500A and 500B is that the capping layer (including the first N-type capping layer 210 or the first N-type capping layer 210 and the second N-type capping layer 212) and the gate layer (the gate structure 208) of the semiconductor device 500C respectively have rectangular cross-sections with different widths.

In this embodiment, the width W2C of the capping layer of the semiconductor device 500C is smaller than the width W1C of the gate layer. In some embodiments in which the capping layer is formed by the first N-type capping layer 210, the width W2C of the first N-type capping layer 210 is smaller than the width W1C of the gate layer. In some embodiments in which the capping layer is formed by the first N-type capping layer 210 and the second N-type capping layer 212, the first N-type capping layer 210 and the second N-type capping layer 212 have the same width (the width W2C), and the above width is smaller than the width W1C of the gate layer.

According to the foregoing, the capping layer and the gate layer of the semiconductor device 500C form a ledged gate structure. In this embodiment, the gate electrode layer 214 and the capping layer of the semiconductor device 500C have the same width W2C.

The difference between the methods for forming the semiconductor device 500C and the semiconductor device 500A (or the semiconductor device 500B) is that in the intermediate processes for forming the semiconductor device 500C, multiple (at least two) patterning processes may be used to form the capping layer and the gate layer with different widths. For example, after performing a patterning process to form the gate layer (the gate structure 208), another patterning process is performed to laterally remove portions of the gate electrode layer and capping layer. Therefore, the sidewalls of the gate electrode layer and the sidewalls of the capping layer are retracted from the sidewalls of the gate layer to form the gate electrode layer 214 and the capping layer of the semiconductor device 500C. In some embodiments, the patterning process may include a photolithography process and a subsequent etching process. The etching process may include wet etching or dry etching. Dry etching may include, for example, plasma etching, reactive ion etching, ion milling or inductively coupled plasma etching. coupled plasma etching), or other suitable dry etching processes.

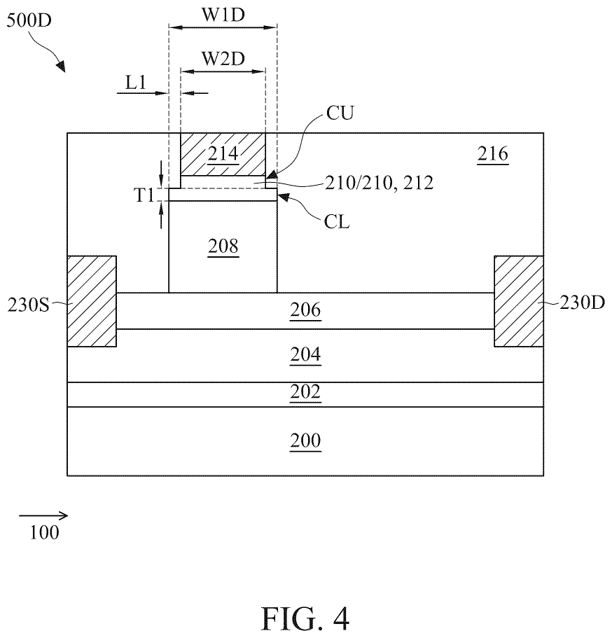

FIG. 4 is a schematic cross-sectional view of a semiconductor device 500D in accordance with some embodiments of the disclosure, in which the reference numbers the same or similar to those in FIGS. 1 to 3 denote the same or similar element. At least one of the differences between the semiconductor device 500D and the semiconductor devices 500A and 500B is that the capping layer (including the first N-type capping layer 210, or the first N-type capping layer 210 and the second N-type capping layer 212) of the semiconductor device 500D has a ledged shaped cross section.

In this embodiment, the capping layer of the semiconductor device 500D has an upper portion CU and a lower portion CL. The lower portion CL is in contact with the gate layer (the gate structure 208) and has the same width W1D as the gate layer. The upper portion CU is in contact with the gate electrode layer 214. Furthermore, the width W2D of the upper portion CU is smaller than the width W1D of the lower portion CL. Therefore, the capping layer and the gate layer of the semiconductor device 500D form a ledged gate structure. In this embodiment, the gate electrode layer 214 of the semiconductor device 500D and the upper portion CU of the capping layer have the same width W2D.

In an embodiment in which the capping layer of the semiconductor device 500D is formed by the first N-type capping layer 210, the width (the width W2D) of the upper portion (the upper portion CU) of the first N-type capping layer 210 is smaller than the width (the width W1D) of the lower portion (the lower portion CL).

In an embodiment in which the capping layer of the semiconductor device 500D is formed by the first N-type capping layer 210 and the second N-type capping layer 212, the lower portion CL of the capping layer may be formed by the first N-type capping layer 210, and the upper portion CU of the capping layer may be formed by the first N-type capping layer 210. Furthermore, the width (the width W2D) of the second N-type capping layer 212 is smaller than the width (the width W1D) of the first N-type capping layer 210.

In some embodiments, the thickness T1 of the lower portion CL may be about 1 nm to 10 nm. In some embodiments, in a direction substantially parallel to the top surface of the substrate 200 (the direction 100), the distance L1 between the corresponding side surfaces of the upper portion CU and the lower portion CL may be about 20 nm to 300 nm. If the distance L1 exceeds the above range, the electrical control capability of the gate structure 208 on the channel layer 204 will be reduced (which may lead to an increase in off-state leakage current or an increase in on-resistance).

At least one of the differences between the formation methods for forming the semiconductor device 500D and the semiconductor device 500A (or the semiconductor device 500B) is that in the intermediate processes for forming the semiconductor device 500D, multiple (at least two) patterning processes can be used to form a ledged shaped capping layer. For example, after performing a patterning process to form the gate layer (the gate structure 208), another patterning process is performed to laterally remove a portion of the gate electrode layer and an upper portion of the capping layer. Therefore, the sidewalls of the gate electrode layer and the sidewalls of the upper layer CU of the capping layer are retracted from the sidewalls of the gate layer and the sidewalls of the lower portion CL of the capping layer to form the gate electrode layer 214 and the capping layer of the semiconductor device 500D. The details of the above patterning process may refer to the relevant description of the semiconductor device 500C above, and will not repeat it here.

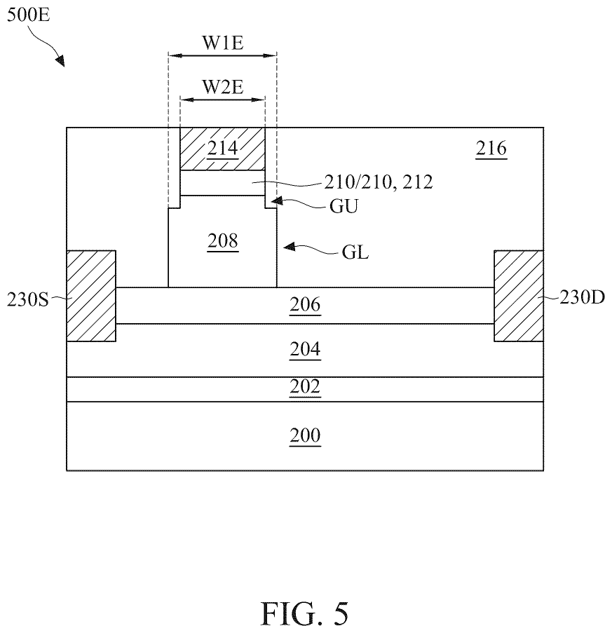

FIG. 5 is a schematic cross-sectional view of a semiconductor device 500E in accordance with some embodiments of the disclosure, in which the reference numbers the same or similar to those in FIGS. 1 to 4 denote the same or similar element. At least one of the differences between the semiconductor device 500E and the semiconductor devices 500A and 500B is that the gate layer (the gate structure 208) of the semiconductor device 500E has a ledge shaped cross section.

In this embodiment, the gate layer (the gate structure 208) of the semiconductor device 500E has an upper portion GU and a lower portion GL. The lower portion GL is in contact with the barrier layer 206. In addition, the lower portion GL has a width W1E. The upper portion GU is in contact with the capping layer. Furthermore, the width W2E of the upper portion GU is smaller than the width W1E of the lower portion GL. Therefore, the capping layer and the gate layer of the semiconductor device 500E form a ledge gate structure.

In this embodiment, the gate electrode layer 214, the capping layer of the semiconductor device 500E, and the upper portion GU of the gate layer have the same width W2E. In some embodiments in which the capping layer of the semiconductor device 500E is formed by the first N-type capping layer 210, the first N-type capping layer 210 and the upper portion GU of the gate layer have the same width W2E. In some embodiments in which the capping layer of the semiconductor device 500E is formed by the first N-type capping layer 210 and the second N-type capping layer 212, the first N-type capping layer 210 and the second N-type capping layer 212 have the same width (the width W2E). In addition, the width of the first N-type capping layer 210 and the second N-type capping layer 212 is equal to the width W2E of the upper portion GU of the gate layer.

At least one of the differences between the formation methods for forming the semiconductor device 500E and the semiconductor device 500A (or the semiconductor device 500B) is that in the intermediate process for forming the semiconductor device 500E, multi (at least two) patterning processes may be used to form a ledge shaped gate layer (the gate structure 208). For example, after performing a patterning process to form the lower portion GL of the gate layer, another patterning process is performed to laterally remove portions of the gate electrode layer, the capping layer and the upper portion of the gate layer. Therefore, the sidewalls of the gate electrode layer, the sidewalls of the capping layer and the sidewalls of the upper portion GU of the gate layer are retracted from the sidewalls of the lower portion GL of the gate layer to form the gate electrode layer 214, the capping layer and the ledge shaped gate structure 208 of the semiconductor device 500E. The details of the above patterning process may refer to the relevant description of the semiconductor device 500C above, and will not repeat it here.

In some embodiments, in the intermediate processes for forming the semiconductor device 500E, multi (at least two) patterning processes may be used to form a ledge gate layer. The details of the above patterning process may refer to the relevant description of the semiconductor device 500C above, and will not repeat it here.

Embodiments provide a semiconductor device, such as a high electron mobility transistor (HEMT) device. The semiconductor device includes a substrate, a buffer layer, a channel layer, a barrier layer, a gate structure, a first N-type capping layer and a gate electrode layer. The buffer layer is located on the substrate. The channel layer is located on the buffer layer. The barrier layer is located on the channel layer. The gate structure is located on the barrier layer. The first N-type capping layer is located on the channel layer. The first N-type capping layer is lightly doped. The doping concentration of the first N-type capping layer is about 1E16 cm⁻³ to 1E18 cm⁻³. The gate electrode layer is located on the first N-type capping layer.

In some embodiments, the semiconductor device includes a capping layer (the first N-type capping layer) sandwiched between the gate layer (the gate structure) and the gate electrode layer. The equivalent circuit of the capping layer, the gate structure, barrier layer and channel layer may serve as an open-base NPN bipolar-gate. The semiconductor device may serve as a bipolar-gate high electron mobility transistor (BG-HEMT).

In the case that the gate is forward biased, the diode (the diode D1) formed by the capping layer (the first N-type capping layer) and the gate layer (for example, P-type GaN layer) is reverse biased. In some embodiments, the first N-type capping layer is lightly doped (the doping concentration is about 1E16 cm⁻³ to 1E18 cm⁻³), so that the diode may have a larger width of the depletion region. Therefore, under the same peak electric field, the above-mentioned diode may withstand a higher voltage, reduce holes injected from the gate electrode layer, and exhibit lower leakage current.

In addition, in the case that the gate is forward biased, the electric field peak is located within the PN junction of the above-mentioned diode (the diode D1). Therefore, the electrical performance of the semiconductor device is not affected by the interface conditions (such as defects) between the gate structure and the gate electrode layer. The surface electric field of the gate structure may be reduced, and the gate breakdown voltage may be effectively increased.

Since the first N-type capping layer contains aluminum and has a larger energy gap than the gate structure (such as the P-type GaN gate layer), it can effectively suppress hole injection and improve the reliability of the gate layer (such as the P-type GaN layer). degree, and can increase the maximum gate voltage swing. In addition, the aluminum of the first N-type capping layer can further reduce the interface electric field between the gate electrode layer and the first N-type capping layer.

In some embodiments, the collector-emitter breakdown voltage with base open (BV_{CEO}) of the NPN HBT having an open-base circuit configuration determines the maximum gate voltage swing. Furthermore, the doping concentration and the content of aluminum in the first N-type capping layer will affect the collector-emitter breakdown voltage. In some embodiments, since the first N-type capping layer is lightly doped (the doping concentration is about 1E16 cm⁻³ to 1E18 cm⁻³), the collector-emitter breakdown voltage can be significantly increased. Moreover, in some embodiments, in order to both reduce the surface electric field of the gate structure and increase the maximum gate voltage swing, The range of the x value representing the content of aluminum in the first N-type capping layer is greater than 0 and less than (or equal to) 0.3, that is, 0<x≤0.3.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a buffer layer located on the substrate;
a channel layer located on the buffer layer;
a barrier layer located on the channel layer;
a gate structure located on the barrier layer; and
a first N-type capping layer located on the channel layer, wherein the first N-type capping layer is lightly doped; and
a gate electrode layer located on the first N-type capping layer.

2. The semiconductor device as claimed in claim 1, wherein a doping concentration of the first N-type capping layer is 1E16 cm⁻³ to 1E18 cm⁻³.

3. The semiconductor device as claimed in claim 1, wherein the difference between an energy gap of the first N-type capping layer and an energy gap of the channel layer is greater than or equal to 25 meV.

4. The semiconductor device as claimed in claim 1, wherein the first N-type capping layer comprises InₓAl₁₋ₓN, AlₓGa₁₋ₓN or AlₓIn_{y}Ga_{1-x-y}N, where 0<x<1, and 0<y<1.

5. The semiconductor device as claimed in claim 4, wherein 0<x≤0.3.

6. The semiconductor device as claimed in claim 1, wherein the first N-type capping layer is in contact with the gate electrode layer to form a Schottky contact.

7. The semiconductor device as claimed in claim 1, wherein the gate structure is in contact with the first N-type capping layer.

8. The semiconductor device as claimed in claim 1, wherein dopants of the first N-type capping layer comprise silicon, germanium, sulfur, phosphorus or a combination thereof.

9. The semiconductor device as claimed in claim 1, wherein a thickness of the first N-type capping layer is 1 nm to 1000 nm.

10. The semiconductor device as claimed in claim 1, wherein the gate structure has a first width, the first N-type capping layer has a second width, and the first width is greater than the second width; and
the first N-type capping layer comprises:
a first upper portion in contact with the gate electrode layer and having the second width; and
a first lower portion in contact with the gate structure and having a third width, wherein the third width is equal to the first width.

11. The semiconductor device as claimed in claim 1, wherein the gate structure further comprises:
a second N-type capping layer located between the first N-type capping layer and the gate electrode layer, and a doping concentration of the second N-type capping layer is greater than a doping concentration of the first N-type capping layer.

12. The semiconductor device as claimed in claim 11, wherein the doping concentration of the second N-type capping layer is from 1E19 cm⁻³ to 1E20 cm⁻³.

13. The semiconductor device as claimed in claim 12, wherein the second N-type capping layer is in contact with the gate electrode layer to form an ohmic contact.

14. The semiconductor device as claimed in claim 12, wherein the second N-type capping layer is in contact with the first N-type capping layer.

15. The semiconductor device as claimed in claim 14, wherein the second N-type capping layer comprises InₓAl₁₋ₓN, AlₓGa₁₋ₓN or AlₓIn_{y}Ga_{1-x-y}N, where 0<x≤0.3, 0<y<1.

16. The semiconductor device as claimed in claim 11, wherein dopants of the second N-type capping layer comprise silicon, germanium, sulfur, phosphorus or a combination thereof.

17. The semiconductor device as claimed in claim 11, wherein a thickness of the second N-type capping layer is from 1 nm to 1000 nm.

18. The semiconductor device as claimed in claim 1, wherein an equivalent circuit of the first N-type capping layer, the gate structure, the barrier layer and the channel layer is an open-base NPN bipolar-gate.
